(19) United States
(12) Patent Application Publication
(10) Pub. No.: US 2018/0324954 A1
(43) Pub. Date: Nov. 8, 2018

(54) TREATMENT FLUID EXTRACTING DEVICE AND ETCHING DEVICE COMPRISING THE LATTER

(71) Applicant: Gebr. Schmid GmbH, Freudenstadt (DE)

(72) Inventors: Jürgen Haungs, Freudenstadt (DE); Stefan Rapp, Freudenstadt (DE)

(21) Appl. No.: 15/773,701

(22) PCT Filed: Oct. 19, 2016
(86) PCT No.: PCT/EP2016/075029

§ 371 Date: May 4, 2018

(30) Foreign Application Priority Data
Nov. 4, 2015 (DE) 10 2015 221 646.2

(51) Int. Cl. H05K 3/06; H01L 21/67; H01L 21/677

(52) U.S. Cl. CPC H05K 3/068; H01L 21/6708; H05K 2203/1545; H05K 2203/075; H05K 2203/082; H01L 21/6776

(57) ABSTRACT

The invention relates to a suction-extraction apparatus for extracting a treatment fluid by suction from an essentially planar treatment surface (3a) of treatment substrates (3) transported by means of transporting rollers (8, 10) along an essentially horizontal transporting direction, having a suction source, having a suction-extraction-control unit, which activates the same, and having a suction-extraction-tube unit, which is connected to the suction source and has at least one suction-extraction lance, which can have one or more entry-side suction-extraction-nozzle openings positioned at a suction-extraction distance from the treatment surface. The invention also relates to an etching apparatus equipped with such a suction-extraction apparatus. In the case of a suction-extraction apparatus according to the invention, the suction source and the suction-extraction-control unit are designed for a suction-volume flow per suction-extraction lance of at least 30 m³/h and a negative suction pressure of no more than 8 kPa. In addition, or as an alternative, the suction-extraction lance has a comb-like suction-extraction structure with a suction-extraction-collecting tube (17) and a plurality of suction-extraction tubes (18) which extend in a comb-like manner from said collecting tube and have the suction-extraction-nozzle openings (19) on the entry side. Use, for example, for etching printed circuit boards, conductor foils or semiconductor wafers.

The invention relates to a suction-extraction apparatus for extracting a treatment fluid by suction from an essentially planar treatment surface of treatment substrates transported by means of transporting rollers along an essentially horizontal transporting direction, wherein the suction-extraction apparatus has a suction source, a suction-extraction-control unit, which activates the same, and a suction-extraction-tube unit, which is connected to the suction source and has at least one suction-extraction lance, which can have one or more entry-side suction-extraction-nozzle openings positioned at a suction-extraction distance from the treatment surface. The invention also relates to an etching apparatus which is equipped with such a suction-extraction apparatus and is intended for the wet chemical etching of an essentially planar treatment surface of treatment substrates by means of an etching fluid, wherein the etching apparatus also contains at least one etching module with an etching-fluid reservoir as well as etching-fluid-delivery means for delivering the etching fluid from the etching-fluid reservoir to the treatment surface and in addition a transporting unit with transporting rollers for transporting the treatment substrates along an essentially horizontal transporting direction, and the suction-extraction apparatus is intended for extracting the etching fluid by suction from the treatment surface. Such etching apparatuses are used, for example, for the wet chemical surface etching of printed circuit boards, conductor foils or semiconductor wafers.

Laid-open application DE 41 21 032 A1 discloses an apparatus for treating plate-like articles with a fluid treatment medium along an essentially horizontal transporting route, wherein the treatment medium is applied by means of an application apparatus, or by means of an upright shaft, to a surface which is to be treated. Arranged upstream or downstream of the site of application of the treatment medium, as seen in the transporting direction, are suction-extraction tubes with suction-extraction openings, which are directed towards the surface which is to be treated and extend essentially over the entire width of the transporting route. This arrangement of the suction-extraction openings makes it possible to define and delimit the extent, as seen along the transporting direction, of the treated surface region, which is in contact with the treatment medium at the point in time of treatment. The suction-extraction tubes each contain a suction nozzle, wherein the suction nozzles are coupled to a container which is intended for separating off suction-extracted liquid and air fractions and, for its part, is connected to a vacuum pump which supplies the negative pressure for the suction nozzles.

A further suction-extraction apparatus of the type mentioned in the introduction is disclosed as being used in an apparatus for the spray treatment of printed circuit boards in laid-open application DE 100 39 558 A1. The suction-extraction device there comprises a suction-nozzle arrangement for extracting a sprayed-on treatment fluid by suction from an upper side of the printed circuit boards during the spraying operation and also comprises a fluid-operated ejector device for generating the negative pressure for the suction-nozzle arrangement, wherein the ejector device is arranged preferably in a storage container, in which the treatment fluid is stored, and is fed from a circulation system for the treatment fluid, said circulation system being equipped with a circulating pump. The ejector device may be provided, in particular, with venturi nozzles.

Laid-open application DE 30 22 146 A1 discloses a suction-extraction apparatus for plate-like articles, such as printed circuit boards pretreated with a liquid medium and with bores passing through them, having a suction head, which can be connected to a suction fan and has at least one suction slot which is closed at its ends and past which the articles can be moved by means of the conveying apparatus in a direction transverse to the longitudinal direction of said suction slot. In order to optimize the suction capacity, a suction-slot covering is provided, said covering comprising a multiplicity of covering elements which can be moved independently of one another between a position in which they cover the suction slot in the appropriate region and a position in which they free the same, wherein they can be controlled by the respective article running past into the freeing open position and return automatically into the covering position after the article has run past.

The invention is based on the technical problem of providing a suction-extraction apparatus of the type mentioned in the introduction which allows for an improved suction extraction of treatment fluid for appropriate applications and, when used in an etching apparatus, can help to improve the etching process. The invention is additionally based on the act of providing a correspondingly improved etching apparatus.

The invention solves this problem by providing a suction-extraction apparatus having the features of Claim 1 and an etching apparatus having the features of Claim 9.

According to one aspect of the invention, the suction source and the suction-extraction-control unit of the suction-extraction apparatus are designed for a suction-volume flow per suction-extraction lance of at least 30 m³/h and a negative suction pressure of no more than 8 kPa. The term negative suction pressure here is intended to mean the differential negative pressure in relation to the surrounding atmosphere. In comparison with suction-extraction apparatuses which are typically used for the present purposes, the suction-extraction apparatus according to the invention is therefore intended to provide a significantly higher suction-volume flow and a significantly lower differential pressure for the suction extraction of the treatment fluid. Consequently, using the suction-extraction apparatus, the treatment fluid is extracted by suction primarily via a comparatively high volume flow and not, as in the case of the conventional suction-extraction apparatuses, primarily via a high differential negative pressure. This gives a solid platform for improved suction-extraction behaviour and, when used in etching apparatuses, for an improved etching process.

The relatively high suction-volume flow per suction-extraction lance, it also being possible for said suction-volume flow for example to range from 200 m³/h to 300 m³/h, and the relatively low differential pressure, it also being possible for said differential pressure for example to be around just 2 kPa to 3 kPa, give rise to appropriately high flow speeds at the suction-extraction-nozzle openings, and therefore the suction-extraction apparatus operates on the principle of flow speed and the suction capacity is not significantly impaired by different media of different densities, such as air and treatment fluid. The use of a comparatively low differential pressure, in addition, reduces the risk of the treatment substrate adhering to the suction-extraction lance.

According to a further aspect of the invention, the suction-extraction lance of the suction-extraction apparatus according to the invention has a comb-like suction-extraction structure with a suction-extraction-collecting tube and a plurality of suction-extraction tubes which extend in a comb-like manner from said collecting tube and on which the suction-extraction-nozzle openings are provided on the entry side. In appropriate application cases, said comb-like suction-extraction structure provides a considerably improved suction-extraction behaviour in that the treatment fluid applied to the treatment surface can be extracted by suction from the latter again very uniformly and effectively. The two aspects of the invention can, particularly advantageously, be combined with one another as desired.

For applications in which the respective transporting roller is provided with transporting-roller members spaced apart on it, an advantageous development of the invention is one in which the suction-extraction tubes of the comb-like suction-extraction structure extend from the suction-extraction-collecting tube into interspaces between the transporting-roller members of the transporting roller. It is thus possible for the treatment fluid to be extracted by suction in a region very close to the relevant transporting roller, and this may be advantageous for good and uniform suction extraction of the treatment fluid.

In a further configuration of said measure, the suction-extraction tubes have their suction-extraction-nozzle openings terminating at the suction-extraction distance from the treatment surface above a lower level of the transporting-roller members and in a vertical plane which passes through an axis of rotation of the transporting roller, or are spaced apart from said vertical plane by at most 10 mm. This arrangement of the suction-extraction-nozzle openings is considerably more advantageous, in many cases, than arranging the same in a region between two successive transporting rollers.

In a further configuration of said measure, the suction-extraction tubes have their suction-extraction-nozzle openings terminating at a distance of at most 7 mm above a lower level of the transporting-roller members. This means that the suction-extraction-nozzle openings are located in the region of a lowermost point of the transporting-roller members or, at any rate, only at a relatively small distance above said lowermost level of the transporting-roller members, as a result of which the suction-extraction behaviour of the suction-extraction apparatus can be further optimized.

In a development of the invention, the suction source comprises a radial fan or a side-channel blower. Suction sources of this type prove to be particularly advantageous for the present suction-extraction apparatus, since they can be used fairly readily for providing the aforementioned high suction-volume flow at only moderate differential negative pressure.

In a development of the invention, the suction source of the suction-extraction apparatus is fitted into a rinsing line by way of a rinsing-line entrance and a rinsing-line exit. This allows, if required, straightforward rinsing of the suction source in order to clean it, for example, of residues of the suction-extracted treatment fluid.

In a development of the invention, the suction-extraction apparatus contains a treatment-medium-collecting tank, which is connected at an entrance to the at least one suction-extraction lance and at an exit to the suction source and has an effective flow cross section which is larger than an effective flow cross section of the at least one suction-extraction lance which opens out into the same. This makes it possible for the suction-extraction speed to drop considerably in the region of the collecting tank, which assists in the collection or separating off of the treatment medium from the suction stream. It is thus possible for the liquid treatment medium to be separated from the gaseous suction-flow fraction in the collecting tank.

In one configuration of this measure, the suction-extraction-collecting tube of the respective suction-extraction lance is arranged with a slope in the direction of the treatment-medium-collecting tank. This assists in the task of transporting in the direction of the collecting tank the treatment fluid which has been extracted from the treatment surface by suction.

The etching apparatus according to the invention is equipped with the suction-extraction apparatus according to the invention and thus makes correspondingly advantageous etching processes possible.

In a development of the invention, the etching-fluid-collecting tank of the suction-extraction apparatus provided in the etching apparatus is arranged at a level above the reservoir of the etching fluid, and a return line leads from the etching-fluid-collecting tank to the etching-fluid reservoir. This allows suction-extracted etching fluid to pass back automatically again, under gravitational force, from the collecting tank into the reservoir.

Advantageous embodiments of the invention will be described hereinbelow and are illustrated in the drawings, in which:

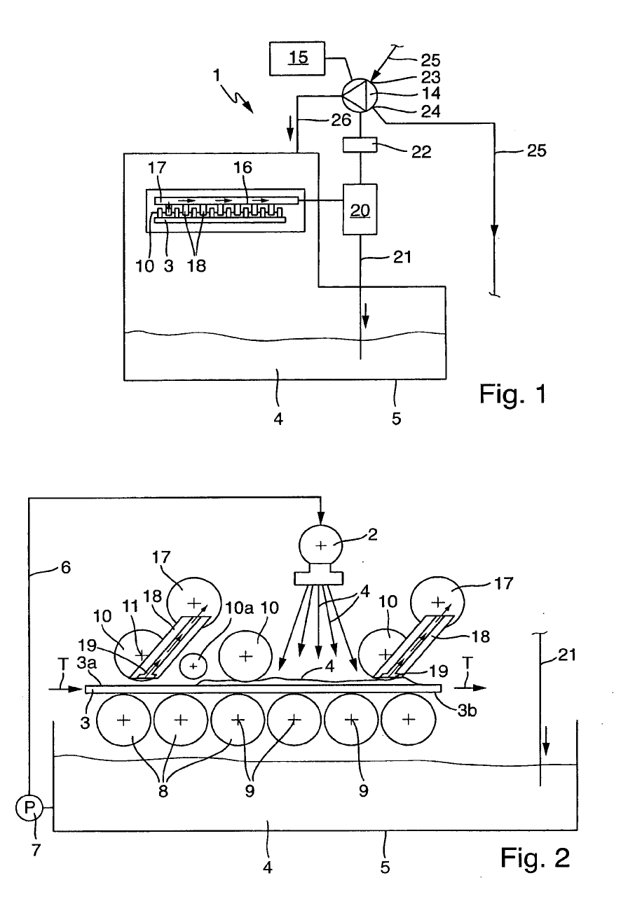

FIG. 1 shows a schematic block-diagram illustration of an etching apparatus for the wet chemical etching of essentially planar treatment substrates,

FIG. 2 shows a more detailed schematic perspective view from the side of the etching apparatus from FIG. 1 in a substrate-treatment region,

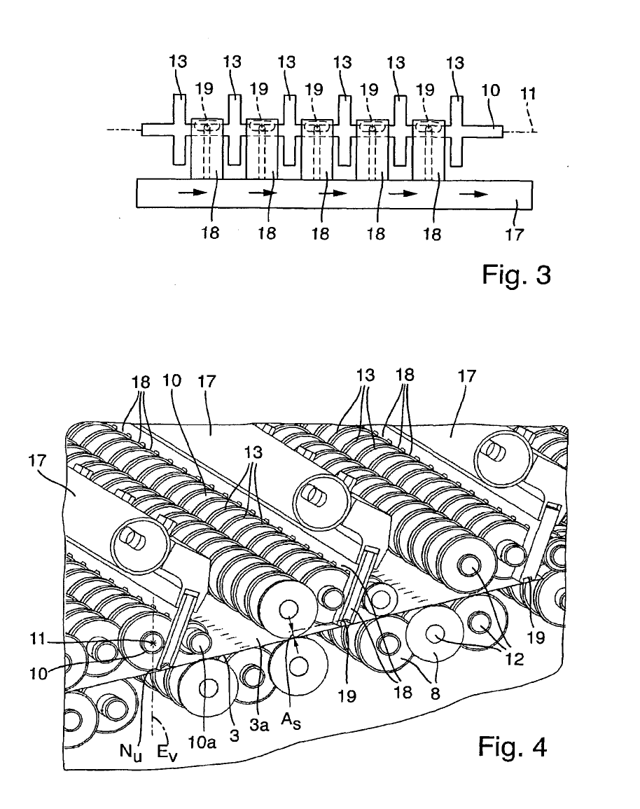

FIG. 3 shows a schematic plan view of the region of a transporting roller from FIG. 2,

FIG. 4 shows, in detail form, a perspective view from the side of a substrate-treatment region similar to that from FIG. 2, and

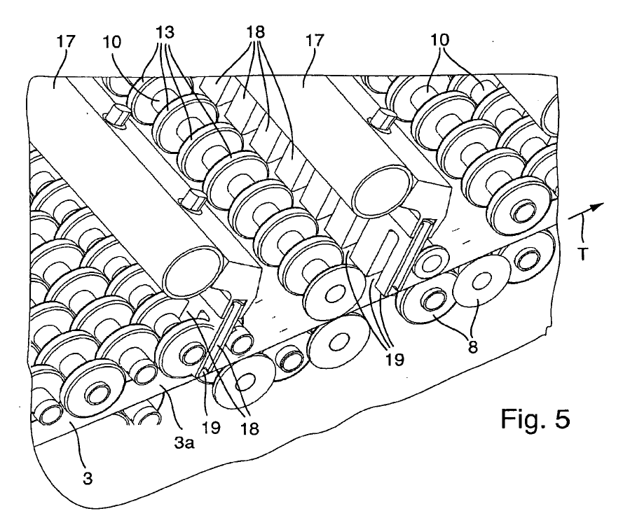

FIG. 5 shows a detail-form view of FIG. 4, one transporting roller having been omitted.

FIGS. 1 to 5 depict an etching apparatus and a suction-extraction apparatus integrated therein as an exemplary realization of the invention. In the embodiment shown, the etching apparatus contains one or more etching modules 1, wherein the respective etching module 1 has at least one spray, flow or hybrid etching unit 2 above a transporting level, on which substrates 3 which are to be treated are transported. The substrates 3 which are to be treated may be, in particular, printed circuit boards, conductor foils, semiconductor wafers or other essentially planar treatment substrates.

The spray, flow or hybrid etching unit 2 serves for applying an etching fluid 4 to an essentially planar surface which is to be treated, in the example shown to an upper side 3a of the treatment substrate 3. The spray/flow or hybrid etching unit 2 is therefore also referred to here as an etching-fluid-application unit or application unit for short. In alternative embodiments, the application unit 2 may be arranged beneath the substrate-transporting level so that the treatment fluid, in this case specifically the etching fluid 4, can be applied to an underside 3b of the substrates 3 which are to be treated. If required, it is also possible for the etching module 1 to contain a plurality of application units 2 which are all arranged above the substrate-transporting level, all beneath the same or some above and some beneath. The treatment or etching fluid 4 is stored in an etching-fluid reservoir 5 and is fed to the respective application unit 2 via a fluid-feed line 6, into which a delivery pump 7 is fitted.

For the treatment, in this case the etching treatment, the treatment substrates 3 are transported in an essentially horizontal transporting direction T by means of a transporting apparatus, which contains a lower row of successive transporting rollers 8 which are spaced apart from one another in the transporting direction T, are each retained such that they can be rotated about their longitudinal axis 9 and on which the substrates 3 rest. In the exemplary embodiments shown, the transporting apparatus comprises, in addition, optional transporting rollers 10 on the upper side, these each being arranged opposite the lower transporting rollers 8, as seen in relation to the transporting plane, and likewise being retained such that they can be rotated about their longitudinal axis 11. These upper transporting rollers 10 function as holding-down means, in particular in applications in which the treatment substrates 3 are relatively thin, for example thin conductor foils with a thickness of only approximately 50 μm or, in more general terms, a thickness smaller than 1 mm. As can be seen from FIGS. 4 and 5, the lower and upper transporting rollers 8, 10 are of identical construction with a central shaft 12 and transporting-roller members 13 spaced apart in a rotationally fixed manner thereon. Transporting apparatuses of this type are familiar to a person skilled in the art, and therefore need not be explained in any more detail.

It is preferably possible for the application unit 4, in order to achieve good etching results, to make use of dual nozzles, which mix the etching fluid, i.e. the etching agent, with a gas. This is expedient in particular for applications in which comparatively fine structures, i.e. those with a relatively small structure width, are to be etched. The mixing with a gas, such as air, can give rise to relatively small droplets of etching agent striking the treatment surface with high energy. It is also the case that this so-called hybrid etching process is familiar to a person skilled in the art, and it therefore does not need to be explained in any more detail here. The dual nozzles have a further advantageous influence on the etching agent, specifically when the latter is used up by the etching process and has to be regenerated. In the dual nozzle, the etching agent can be brought into close contact, for example, with air for oxidizing regeneration purposes, e.g. in the case of an alkaline etching medium such as copper chloride. As an alternative, or in addition, to such a use of dual nozzles, the present invention makes it possible for the etching fluid, during the suction extraction from the treatment surface, to be brought into contact with atmospheric oxygen for regenerative oxidation purposes. This can also render superfluous, or reduce, the use of some other regeneration agent, such as hydrogen peroxide.

A suction-extraction apparatus for extracting the etching fluid 4 by suction from the treatment surface 3a of the treatment substrates 3 is integrated in the etching apparatus shown, wherein said suction-extraction apparatus can also be used elsewhere for extracting any desired treatment fluid by suction from an essentially planar treatment surface of treatment substrates which are transported by means of transporting rollers along an essentially horizontal transporting direction. The treatment fluid may be, e.g. apart from an etching fluid, also a cleaning fluid, etc.

The suction-extraction apparatus contains a suction source 14, a suction-extraction-control unit 15, which activates the same, and a suction-extraction-tube unit, which is connected to the suction source and has one or more suction-extraction lances 16. For example it is possible for between five and twenty suction-extraction lances 16 to be provided per etching module 1. Depending on requirements and the application case, it is possible for a respective suction-extraction lance 16 to be arranged upstream and/or downstream of each treatment-fluid-application unit 2, as seen in the transporting direction T. The suction source 14 and the suction-extraction-control unit 15 are designed for supplying a suction-volume flow per suction-extraction lance 16 of at least 30 m³/h, preferably of approximately 100 m³/h to 300 m³/h, and a differential pressure, in the form of a negative suction pressure, of no more than 8 kPa, preferably of, for example, between 2 kPa and 3 kPa.

The respective suction-extraction lance 16 has a comb-like suction-extraction structure with a suction-extraction-collecting tube 17 and a plurality of suction-extraction tubes 18 which extend in a comb-like manner from said collecting tube and are each provided with one or more suction-extraction-nozzle openings 19 on the entry side. The collecting tube 17 preferably has an effective cross section which is considerably larger than the sum of the effective cross sections of the suction-extraction tubes 18 which open out into the same. The collecting tubes 17 of the suction-extraction lances 16 open out into a common collecting tank 20, which is arranged upstream of the suction source 14. An effective flow cross section of the collecting tank 20 is selected such that it is larger than an effective flow cross section of the collecting tubes 17 or suction-extraction lances 16 which open out into the same, preferably at least double the size and preferably more than five times the size. It is thus possible for the collecting tank 20 to assist in separating off the sucked-in fluid from the gaseous constituent parts of the suction flow. As an optional measure, it is advantageous if the suction-extraction-collecting tube 17 of the respective suction-extraction lance 16 is arranged with a slope in the direction of the collecting tank 20, which assists, or ensures, the transportation of the suction-extracted fluid in the collecting tube 17. Provision may expediently be made for the collecting tank 20 to be arranged at a level above a maximum liquid level of the treatment fluid 4 in the reservoir 5. The treatment fluid collected in the collecting tank 20 can then flow back into the reservoir 5 again via an associated return line 21, as shown, solely under gravitational force, even though there is a negative pressure prevailing in the collecting tank 20.

A condensate separator 22 may be arranged between the collecting tank 20 and the suction source 14. A further option is for the suction source 14 to be fitted into a rinsing line 25 by way of a rinsing-line entrance 23 and a rinsing-line exit 24, as a result of which the suction source 14 can be rinsed if required. A return means may be provided, if required, for the rinsing fluid, e.g. rinsing water, used. In order to ensure an equalized pressure balance within the etching module 1, a return line 26 is optionally routed from the suction source 14 to the etching module 1.

By virtue of the suction-extraction apparatus and specifically the suction source 14 and the suction-extraction-control unit 15 being designed, as already mentioned, for relatively high suction-volume flow at a relatively low differential pressure, the suction-extraction apparatus operates by the principle of flow speed. In this case, the high volume flow in conjunction with a suitably small suction-extraction distance of the suction-extraction-nozzle openings 19 from the treatment surface 3a covered by the fluid 4 which is to be extracted by suction achieves a high suction-flow speed and therefore a suction-nozzle effect by which the treatment-fluid/air mixture is carried along and extracted by suction. The low negative pressure, rather than being required primarily for suction-extraction purposes in this suction-extraction principle, is required, in particular, to transport the suction-extracted fluid over the present height difference counter to the hydrostatic pressure. In relation to the conventional method of extracting the fluid by suction at a high negative pressure and with a low volume flow, this method has the significant advantage that the suction-extraction operation takes place to a sufficient extent even when the suction-extraction lance 16 does not have its suction-extraction-nozzle openings 19 fully immersed in the fluid and, as a result, sucks in air in addition. In the case of the conventional method, this results, due to the failing negative pressure, to a considerable drop in the suction capacity, whereas, the suction-extraction method used here does not significantly influence the suction capacity as a result of different media of different densities, such as treatment fluid and air. In an analogous manner, it is also the case that the suction capacity is not vastly impaired by any gaps between two successive substrates 3 or by empty spaces in the case of substrates 3 of different widths being treated.

The suction source 14 which can be used is, in particular, a radial fan or a side-channel blower or similar conventional fan which is suitable for the said volume flow. Where arrows are shown in the figures and are not referred to elsewhere, they represent the flow channelled there in each case, for example the suction flow, the feed flow of etching agent and/or the rinsing-fluid flow.

The comb-like suction-extraction structure makes it possible, as provided for in the exemplary embodiment shown, for the suction-extraction tubes 18 extending from the suction-extraction-collecting tube 17 to be arranged in interspaces between the transporting-roller members 13 of a respective transporting roller, in this case of a respective upper transporting roller 10, as can be seen, in particular, from FIGS. 3 to 5. The suction-extraction tubes 18 here have their suction-extraction-nozzle openings 19 terminating at a predeterminable suction-extraction distance Aₛ from the treatment surface 3a above a lower level Nᵤ of said transporting-roller members 13 and in a vertical plane Eᵥ which passes through the axis of rotation 11 of the relevant transporting roller 10, or at a horizontal distance of at most 10 mm from said vertical plane Eᵥ. In addition, or as an alternative, it is possible for the suction-extraction tubes 18 to have their suction-extraction-nozzle openings 19 arranged such that they terminate at a distance of at most 7 mm above the lower level Nᵤ of said transporting-roller members 13, wherein the suction-extraction tubes 18 extend vertically or obliquely downwards, from the higher-level collecting tube 17, into the interspaces between the transporting-roller members 13 of the respective transporting roller 10. If, as in the example shown, the upper transporting rollers 10 with their transporting-roller members 13 function as holding-down means for the treatment substrates 3, the lower level Nᵤ of said transporting-roller members 13 corresponds essentially to the level of the substrate upper side 3a which is to be treated, and therefore the vertical distance of the suction-extraction-nozzle openings 19 from the lower level Nᵤ of the transporting-roller members corresponds to the suction-extraction distance Aₛ of said openings from the treatment surface 3a. A small suction-extraction distance Aₛ increases the suction-flow speed and thus is favourable for the suction result.

Arranging the suction-extraction tubes 18 with their suction-extraction-nozzle openings 19 between the transporting-roller members 13 of at least some of the upper transporting rollers 10 and at, at most, a small distance from the lowermost point of said transporting-roller members 13 and, at most, a small horizontal distance from the vertical centre plane Eᵥ of said transporting roller 10, as seen in the transporting direction T, is favourable for good extraction of the treatment fluid 4 by suction from the treatment surface 3a and, at the same time, avoids adherence of the substrates 3 on account of the negative suction pressure. This is because it is at this location directly in the region of the lowermost point between the transporting-roller members 13 of a respective upper transporting roller 10 that the substrate 3 is held down by the transporting-roller members 13 and cannot move in the direction of the suction-extraction-nozzle openings 19. In the case of constricted space conditions, it may be expedient, as shown, for a transporting roller adjacent to the respective suction-extraction lance 16 to be designed in the form of a smaller-diameter transporting roller 10a, which is modified in relation to the other transporting rollers 10.

The suction-extraction lances 16 can be retained in a fixed state on the etching or treatment module 1. In an advantageous alternative embodiment, they are arranged in a height-adjustable manner in the treatment module 1. It is preferably possible for them here to be coupled to a substrate-advancement controller such that, with the suction-extraction distance of the suction-extraction-nozzle openings 19 from the treatment surface 3a remaining essentially constant, treatment substrates 3 of different thicknesses can be processed automatically without, for this purpose, the respective suction-extraction lance 16 having to be adjusted by hand. Instead, the suction-extraction lance 16 is then height-adjusted by the relevant controller in dependence on the treatment-substrate thickness which is present in each case, and can be detected, e.g. by sensors. This can be done, for example, synchronously with a corresponding height adjustment of the upper transporting rollers 10, which function as holding-down means. In an embodiment which is advantageous in this regard, the respective suction-extraction lance 16 is mounted in a fixed state on the respective height-adjustable upper transporting roller 10, and it is therefore height-adjusted automatically therewith when the thickness of the treatment substrates 3 changes.

Depending on requirements and the application case, it is possible, in addition to just the controller of the suction source 14, for further suction-extraction-controller measures to be implemented in the suction-extraction-control unit 15. It is thus possible, for example, optionally for valves to be installed at suitable locations of the suction-extraction lances 16, and for the presence of a substrate 3 which is to be treated to be monitored by sensors. The suction-extraction-control unit 15 can then activate the valves in the suction-extraction lances 16 such that the suction-extraction lance 16 is active in terms of suction only at the times when a treatment substrate 3 is located beneath its suction-extraction-nozzle openings 19. As a further option, throttles may be installed at suitable locations of the suction-extraction lances 16, and these throttles can be adjusted manually or with control via the suction-extraction-control unit 15 in order to set the same suction-extraction capacity in the individual suction-extraction-nozzle openings 19. In a similar manner, provision may be made for the application units 2 to be activated and deactivated in a specific manner via valves. This makes it possible for the etching operation to be locally set, and/or influenced, in a very specific manner.

As is made clear by the embodiments which have been disclosed and explained above, the invention very advantageously makes available a suction-extraction apparatus by means of which a treatment fluid can be extracted by suction from an essentially planar treatment surface of an essentially horizontally transported treatment substrate, wherein the treatment fluid may be in particular an etching fluid or a cleaning fluid and the treatment substrates may be in particular semiconductor wafers, printed circuit boards, conductor foils of certain dimensions or endless conductor foils. The suction-extraction apparatus can be used particularly advantageously in an etching apparatus for the wet chemical etching of such treatment substrates.

1. A suction-extraction apparatus for extracting a treatment fluid (4), in particular an etching fluid, by suction from an essentially planar treatment surface of treatment substrates, in particular printed circuit boards or conductor foils or semiconductor wafers, transported by means of transporting rollers along an essentially horizontal transporting direction,
having a suction source,
having a suction-extraction-control unit, which activates the suction source, and
having a suction-extraction-tube unit, which is connected to the suction source and has at least one suction-extraction lance, which can have one or more entry-side suction-extraction-nozzle openings positioned at a suction-extraction distance from the treatment surface,
wherein
the suction source and the suction-extraction-control unit are designed for a suction-volume flow per suction-extraction lance of at least 30 m³/h and a negative suction pressure of no more than 8 kPa, and/or
the suction-extraction lance has a comb-like suction-extraction structure with a suction-extraction-collecting tube and a plurality of suction-extraction tubes which extend in a comb-like manner from said collecting tube and have the suction-extraction-nozzle openings on the entry side.

2. The suction-extraction apparatus according to claim 1, wherein the suction-extraction tubes of the comb-like suction-extraction structure extend from the suction-extraction-collecting tube into interspaces between transporting-roller members of one of the transporting rollers, said members being spaced apart from one another on the transporting roller.

3. The suction-extraction apparatus according to claim 2, wherein the suction-extraction tubes have their suction-extraction-nozzle openings terminating at the suction-extraction distance from the treatment surface above a lower level of the transporting-roller members and in a vertical plane which passes through an axis of rotation of the transporting roller, or are spaced apart from said vertical plane by at most 10 mm.

4. The suction-extraction apparatus according to claim 2, wherein the suction-extraction tubes have their suction-extraction-nozzle openings terminating at a distance of at most 7 mm above a lower level of the transporting-roller members.

5. The suction-extraction apparatus according to claim 1, wherein the suction source comprises a radial fan or a side-channel blower.

6. The suction-extraction apparatus according to claim 1, wherein the suction source is fitted into a rinsing line by way of a rinsing-line entrance and a rinsing-line exit.

7. The suction-extraction apparatus according to claim 1, wherein a treatment-medium-collecting tank, which is connected at an entrance to the at least one suction-extraction lance and at an exit to the suction source and which has an effective flow cross section which is larger than an effective flow cross section of the at least one suction-extraction lance which opens out into the same.

8. The suction-extraction apparatus according to claim 7, wherein the suction-extraction-collecting tube of the respective suction-extraction lance is arranged with a slope in the direction of the treatment-medium-collecting tank.

9. An etching apparatus for the wet chemical etching of an essentially planar treatment surface of treatment substrates, in particular of printed circuit boards or conductor foils or semiconductor wafers, by means of an etching fluid,
having at least one etching module with an etching-fluid reservoir,
having etching-fluid-delivery means for delivering the etching fluid from the etching-fluid reservoir to the treatment surface,
having a transporting unit with transporting rollers for transporting the treatment substrates along an essentially horizontal transporting direction, and
having a suction-extraction apparatus for extracting the etching fluid by suction from the treatment surface,
wherein
the suction-extraction apparatus is one such according to claim 1.

10. The etching apparatus according to claim 9, wherein the etching-fluid-collecting tank of the suction-extraction apparatus is arranged at a level above the etching-fluid reservoir and a return line leads from the etching-fluid-collecting tank to the etching-fluid reservoir.
